(19) United States
(12) Patent Application Publication
(10) Pub. No.: US 2021/0057238 A1
(43) Pub. Date: Feb. 25, 2021

(54) METHODS AND APPARATUS FOR CONTACTLESS SUBSTRATE WARPAGE CORRECTION

(71) Applicant: APPLIED MATERIALS, INC., Santa Clara, CA (US)

(72) Inventors: CHIN WEI TAN, SINGAPORE (SG); QI JIE PENG, SINGAPORE (SG); FANG JIE LIM, SINGAPORE (SG); PRAYUDI LIANTO, SINGAPORE (SG); SRISKANTHARAJAH THIRUNAVUKARASU, SINGAPORE (SG); ARVIND SUNDARRAJAN, SINGAPORE (SG); JUN-LIANG SU, Singapore (SG)

(21) Appl. No.: 16/545,752

(22) Filed: Aug. 20, 2019

(51) Int. Cl. H01L 21/67; H01L 21/683; H01L 21/687

(52) U.S. Cl. CPC H01L 21/67109; H01L 21/67248; H01L 21/68742; H01L 21/6838; H01L 21/67288

(57) ABSTRACT

Embodiments of methods and apparatus for reducing warpage of a substrate are provided herein. In some embodiments, a method for reducing warpage of a substrate includes heating the substrate with an epoxy layer to at least a glass transition temperature of the epoxy layer while allowing the substrate to expand; subsequently constraining the substrate with a clamping force exerted towards the substrate from a top direction by applying a high pressure gas to the substrate and from a bottom direction by applying a vacuum pressure to the substrate; and rapidly cooling the substrate while the substrate is constrained.

### FIELD

Embodiments of the present disclosure generally relate to substrate processing equipment.

### BACKGROUND

Warped substrates prevent the substrates from being chucked fully on a process station pedestal. Such warpage leads to a delay in or ceasing of the substrate processing. For example, a substrate may comprise multiple dies on an interposer and encapsulated with an epoxy mold compound or a substrate may comprise multiple exposed dies. These substrates may bow and warp after thermal processes due to inhomogeneous heating and cooling, causing non-uniform expansion/contraction rates in current process equipment.

Conventional thermal processes utilize directional heat transfer that results in anisotropic expansion and contraction rates. When operated near the thermoplastic regime, non-uniform cooling and, subsequently, contraction rates give rise to a warped substrate. Such warp and bow effects are frequently observed and imply that the substrate is being processed close to the thermoplastic regime of the substrate, giving rise to substrate warpage beyond acceptable levels. Being able to reduce warpage found in substrates would allow otherwise unusable substrates to be used, dramatically increasing production yields. However, physical contact to reduce warpage of substrates having exposed dies damage the exposed dies.

Accordingly, the inventors have provided improved methods and apparatus for reducing warpage found in substrates.

### SUMMARY

Embodiments of methods and apparatus for reducing warpage of a substrate are provided herein. In some embodiments, a method for reducing warpage of a substrate includes heating the substrate with an epoxy layer to at least a glass transition temperature of the epoxy layer while allowing the substrate to expand; subsequently constraining the substrate with a clamping force exerted towards the substrate from a top direction by applying a high pressure gas to the substrate and from a bottom direction by applying a vacuum pressure to the substrate; and rapidly cooling the substrate while the substrate is constrained.

In some embodiments, a non-transitory, computer readable medium having instructions stored thereon that, when executed, cause a method of reducing warpage of a substrate to be performed, the method including heating the substrate with an epoxy layer to at least a glass transition temperature of the epoxy layer while allowing the substrate to expand; maintaining the at least the glass transition temperature of the substrate until the substrate is constrained; constraining the substrate from a top direction by applying a high pressure gas to the substrate and a bottom direction by applying a vacuum pressure to the substrate via one or more vacuum channels; and rapidly cooling the substrate using a first liquid convection heat sink positioned above the substrate and a second liquid convection heat sink positioned below the substrate.

In some embodiments, an apparatus for reducing warpage of a substrate with an epoxy layer includes a first station comprising a transferable pedestal that holds the substrate, and a heated gas supply disposed opposite the substrate to provide a heated gas to a surface of the substrate, wherein the first station is configured to heat the substrate to at least a glass transition temperature of the epoxy layer; a second station comprising a first cooling module having a substrate support that includes a substrate support surface, a vacuum chuck operatively coupled to the substrate support surface, and cooling channels disposed beneath the substrate support surface, and a second cooling module disposed opposite the first cooling module and having a gas supply and cooling channels, wherein the second station is sealable and pressurizable to create an enclosed volume having the substrate support surface disposed between the first cooling module and the second cooling module and to provide gas from the gas supply at a high pressure to the enclosed volume; and wherein the first station and the second station are configured to transfer the substrate between the first station and the second station with the transferable pedestal while maintaining the at least the glass transition temperature of the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow diagram of a method of reducing warpage in a substrate in accordance with some embodiments of the present principles.

FIG. 2A is a cross-sectional view of a substrate that may be processed in accordance with some embodiments of the present principles.

FIG. 2B is a cross-sectional view of a substrate that may be processed in accordance with some embodiments of the present principles.

FIG. 3 is an illustration of forces applied to a substrate during heating and cooling which may be circumvented in accordance with some embodiments of the present principles.

FIG. 4 is a schematic side view of an apparatus for reducing warpage of a substrate in accordance with some embodiments of the present principles.

FIG. 5 is a top view of an apparatus for reducing warpage of a substrate in accordance with some embodiments of the present principles.

FIGS. 6A-6D illustrate a method of reducing warpage of a substrate in accordance with some embodiments of the present principles.

FIG. 7 is a bottom view of an annular gas delivery assembly in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for reducing warpage of a substrate are provided herein. The methods and apparatus reduce warpage of substrates to allow subsequent semiconductor processing. When a substrate has warpage greater than 2 mm, the substrate is generally deemed unusable. Even backgrinding processes require less than 2 mm in warpage in order to be utilized. In semiconductor back end of the line (BEOL) packaging, 2.5D is a methodology for including multiple dies inside the same package. The 2.5D approach is used for applications where performance and low power are critical. In a 2.5D wafer, communication between chips is established using either a silicon or organic interposer, typically a chip or layer with through-silicon vias (TSV) for communication. 2.5D architectures have been paired with stacked memory modules, such as High-Bandwidth Memory (HBM), to further improve performance. High warpage of 2.5D wafers is a pressing industrial problem as the warpage prevents the 2.5D wafers from flowing on to downstream processes. Wafer handling challenges and reduction in yield are the most common detrimental effects of high 2.5D wafer warpage. The methods and apparatus of the present principles may be applied to advantageously correct warpage of a 2.5D wafer which is fully encapsulated with epoxy mold compound, which has exposed dies, or to correct warpage of any multilayer substrates. The methods and apparatus reduce warpage using only two thermal treatments, saving time and possible damage to delicate circuits, especially those sensitive to thermal budgets and smaller structures that are more easily damaged by thermal changes.

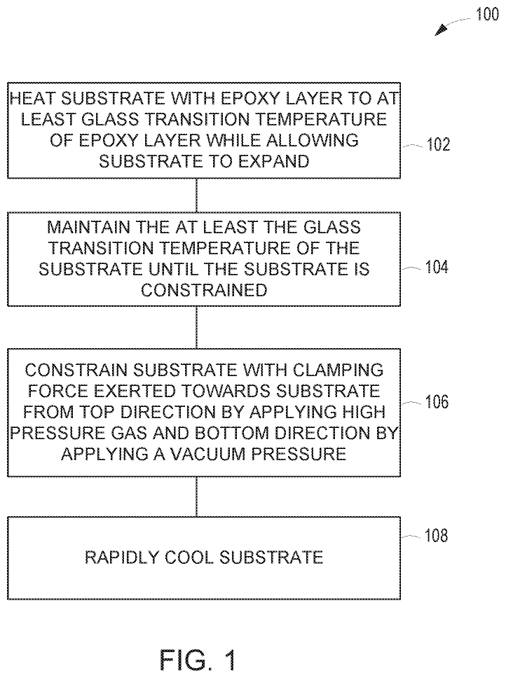

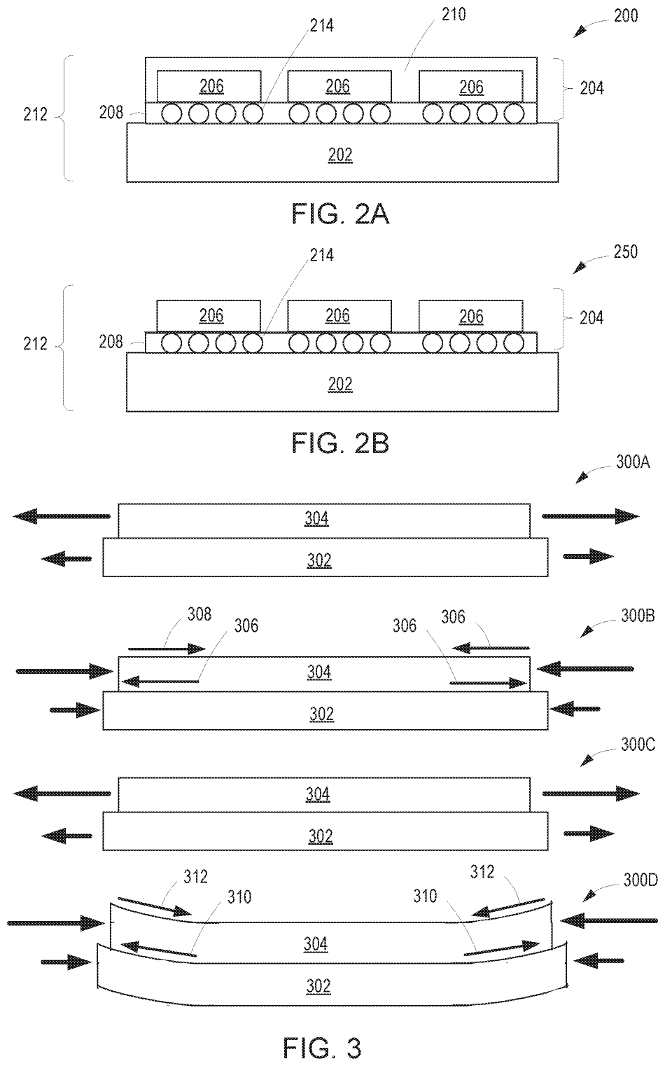

FIG. 1 is a method 100 of reducing warpage of a substrate 212 as illustrated in FIG. 2A or substrate 250 as illustrated in FIG. 2B and in accordance with some embodiments. FIG. 2A is a cross-sectional view of a substrate 200 that may be processed in accordance with some embodiments of the present principles. FIG. 2B is a cross-sectional view of a substrate 250 that may be processed in accordance with some embodiments of the present principles. In some embodiments, the substrate 212 may include an interposer layer 202. In some embodiments, as shown in FIG. 2A, the substrate 200 includes an epoxy mold encapsulation layer 204. The epoxy mold encapsulation layer 204 may include epoxy mold 210, dies 206 embedded in the epoxy mold 210, and an epoxy mold under fill layer 208. The epoxy mold under fill layer 208 may also include solder bumps 214. In some embodiments, as shown in FIG. 2B, the epoxy mold encapsulation layer 204 does not include the epoxy mold 210 such that dies 206 disposed on the epoxy mold under fill layer 208 are exposed.

At 102, the substrate 212 or the substrate 250 is heated to a temperature that is at least a glass transition temperature of the epoxy material used in the epoxy mold encapsulation layer 204 while allowing the substrate 212 or the substrate 250 to freely expand. The epoxy material may vary and, subsequently, the glass transition temperature will also vary. In addition, some epoxy materials utilize fillers in the epoxy material which also may influence heating to the glass transition temperature. In some embodiments, the glass transition temperature of the epoxy material may be from approximately 100 degrees Celsius to approximately 200 degrees Celsius. In some embodiments, the glass transition temperature of the epoxy material may be from approximately 140 degrees Celsius to approximately 180 degrees Celsius.

At 104, the substrate 212, 250 is maintained at the at least glass transition temperature until the substrate 212, 250 is constrained. In some embodiments, the temperature of the substrate 212, 250 is maintained to at least the glass transition temperature of the epoxy material during transfer of the substrate 212, 250 from a heating station to a cooling station. In some embodiments, the temperature may be maintained by using a transferable pedestal (described in detail below) with conduction heating for transferring the substrate 212, 250 between heating and cooling stations. In some embodiments, the temperature may also be maintained by using heated gas dispersed around the substrate (described in detail below) while the substrate is being positioned within a cooling station and until the substrate has clamping forces applied to the substrate.

At 106, the substrate 212, 250 is constrained with a clamping force that is exerted towards the substrate 212, 250 from a top direction by applying high pressure gas and from a bottom direction by applying a vacuum pressure. In some embodiments, the high clamping force may be from approximately 5000N (newtons) to approximately 10,000N (newtons). In some embodiments the high clamping force may be approximately 5000N (newtons). At 108, the substrate 212, 250 is rapidly cooled to lock in the constrained shape of the substrate 212, 250. In some embodiments, at least one liquid convection heat sink may be utilized to rapidly quench cool the substrate 212, 250 while the substrate 212, 250 is constrained to retain the epoxy's elongated and low stress state. The rapid quench cool may occur at a rate of approximately 1300 W/m^{2°}C to a rate of approximately 3100 W/m^{2°}C.

The constraining of the substrate 212, 250, the application of the vacuum pressure and the high pressure gas to the substrate 212, 250, and the rapid cooling of the substrate 212, 250 are accomplished approximately concurrently. In some embodiments, the concurrent constraining of the substrate 212, 250, cooling of the substrate 212, 250, and applying the vacuum pressure and high pressure gas to the substrate 212, 250 occurs for approximately 120 seconds to approximately 600 seconds.

FIG. 3 is an illustration of forces applied to a substrate during heating and cooling which may be mitigated in accordance with some embodiments. In view 300A, the substrate is being heated. An interposer layer 302 expands during heating but with a coefficient of thermal expansion (CTE) of less than half the CTE of an epoxy mold encapsulation layer 304. In view 300B, the substrate is being cooled causing thermal contraction. Because of the differences in CTE, the epoxy mold encapsulation layer 304 contracts more than the interposer layer 302. Tensile stress forces 306 result at the union of the epoxy mold encapsulation layer 304 and the interposer layer 302 because of the differences in CTE. The differences in CTE also cause compressive stress forces 308 to form at an upper portion of the epoxy mold encapsulation layer 304. In view 300C, the substrate is cured causing differences in thermal expansion and shrinkage of the epoxy material in the epoxy mold encapsulation layer 304 along with polymerization. The curing establishes the mechanical properties of E.M.C. (Elastic Modulus, CTE a1 and CTE a2). In view 300D, thermal contraction occurs with different forces on each layer when the substrate is cooled after curing. The cured epoxy contraction in the epoxy mold encapsulation layer 304 is restricted by the silicon in the interposer layer 302 during post cure cooling. A higher elasticity modulus of the epoxy material exerts higher stress forces on the silicon. High tensile stress forces 310 form at the bonding interface between the epoxy mold encapsulation layer 304 and the interposer layer 302. High compressive stress forces 312 form at an upper portion of the epoxy mold encapsulation layer 304 which causes both layers to warp after post cure cooling.

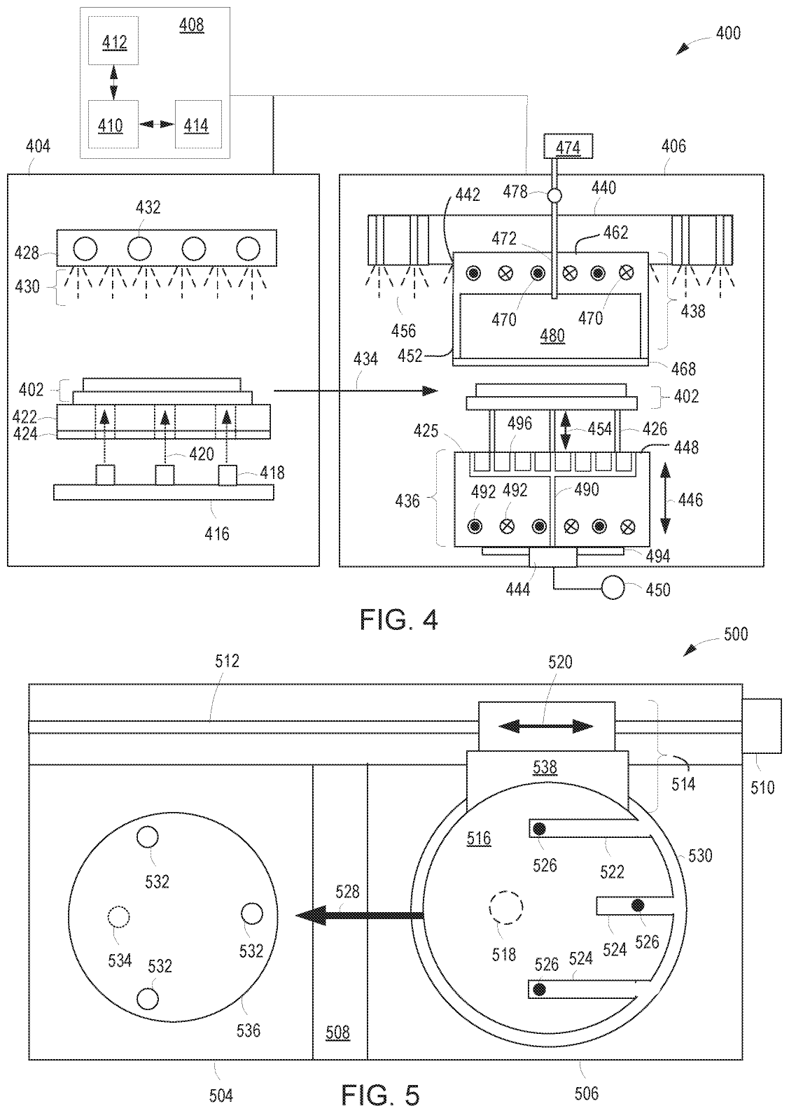

FIG. 4 is a schematic side view of an apparatus 400 for reducing warpage of a substrate 402 in accordance with some embodiments. In some embodiments, the substrate 402 may be substrate 215 or substrate 250. The apparatus 400 includes a first station 404, a second station 406, and a system controller 408. The system controller 408 controls the operation of the apparatus 400 using a direct control of the first station 404 and the second station 406 or alternatively, by controlling the computers (or controllers) associated with the first station 404 and the second station 406. In operation, the system controller 408 enables data collection and feedback from the respective stations and systems to optimize performance of the apparatus 400. The system controller 408 generally includes a Central Processing Unit (CPU) 410, a memory 412, and a support circuit 414. The CPU 410 may be any form of a general purpose computer processor that can be used in an industrial setting. The support circuit 414 is conventionally coupled to the CPU 410 and may comprise a cache, clock circuits, input/output subsystems, power supplies, and the like. Software routines, such as the methods described herein may be stored in the memory 412 or other computer readable media and, when executed by the CPU 410, transform the CPU 410 into a specific purpose computer (system controller 408). The software routines may also be stored and/or executed by a second controller (not shown) that is located remotely from the apparatus 400.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

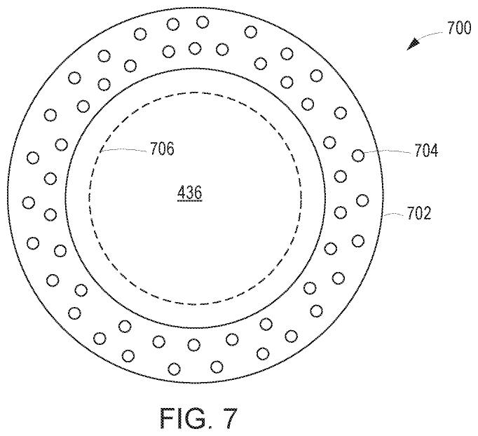

In some embodiments, the first station 404 may include a heat sensor assembly 416 that includes at least one heat sensor 418 that is configured to read 420 a bottom surface of the substrate 402. In some embodiments, the at least one heat sensor 418 may be an infrared heat sensor and the like. The at least one heat sensor 418 may be in communication with the system controller 408 to provide feedback on the heating of the substrate 402. The substrate 402 is supported by a transferable pedestal 422. In some embodiments, the transferable pedestal 422 includes a heater 424 bonded to a lower surface of the transferable pedestal 422. In some embodiments, the heater 424 is a conduction heater. The transferable pedestal 422 may be in communication with the system controller 408 to determine a position or status or the like of the transferable pedestal 422. Similarly, the heater 424 may be in communication with the system controller 408 so that the heater 424 can be configured to maintain at least a glass transition temperature of an epoxy material in the substrate 402. In some embodiments, the transferable pedestal 422 may have slots or holes through the transferable pedestal 422 to allow the at least one heat sensor 418 to directly read the bottom surface of the substrate 402 and/or to allow the transferable pedestal 422 to place the substrate 402 on lift pins 426 in the second station 406 (see FIG. 7 below).

The first station 404 may also have a gas distribution assembly 428 above the transferable pedestal 422. The gas distribution assembly 428 provides heated gas 430 to heat the substrate 402 to at least the glass transition temperature of the epoxy material in the substrate 402. The heated gas may be heated by at least one infrared lamp 432 in the gas distribution assembly 428. In some embodiments, the gas distribution assembly 428 provides a gas at a temperature of approximately 200 degrees Celsius to approximately 300 degrees Celsius. In some embodiments, the gas distribution assembly 428 provides a gas at a temperature of approximately 240 degrees Celsius. In some embodiments, the gas distribution assembly 428 provides a gas at a pressure of approximately 1 bar to approximately 2.5 bar. In some embodiments, the gas distribution assembly 428 provides a gas at a pressure of approximately 1 bar to approximately 2 bar. In some embodiments, the gas may be nitrogen, nitrogen/air, and/or other inert gases. The gas distribution assembly 428 (including the at least one infrared lamp) may be in communication with the system controller 408 to configure the first station 404 to heat the substrate 402 to the at least the glass transition temperature of the epoxy material in the substrate 402. The first station 404 heats the substrate 402 to the at least the glass transition temperature of the epoxy material using the heater 424 of the transferable pedestal 422 and the gas distribution assembly 428. When the substrate 402 reaches at least the glass transition temperature of the epoxy material, the heater 424 of the transferable pedestal maintains the at least the glass transition temperature of the epoxy material as the transferable pedestal 422 moves with the substrate 402 into the second station 406 as indicated by the arrow 434.

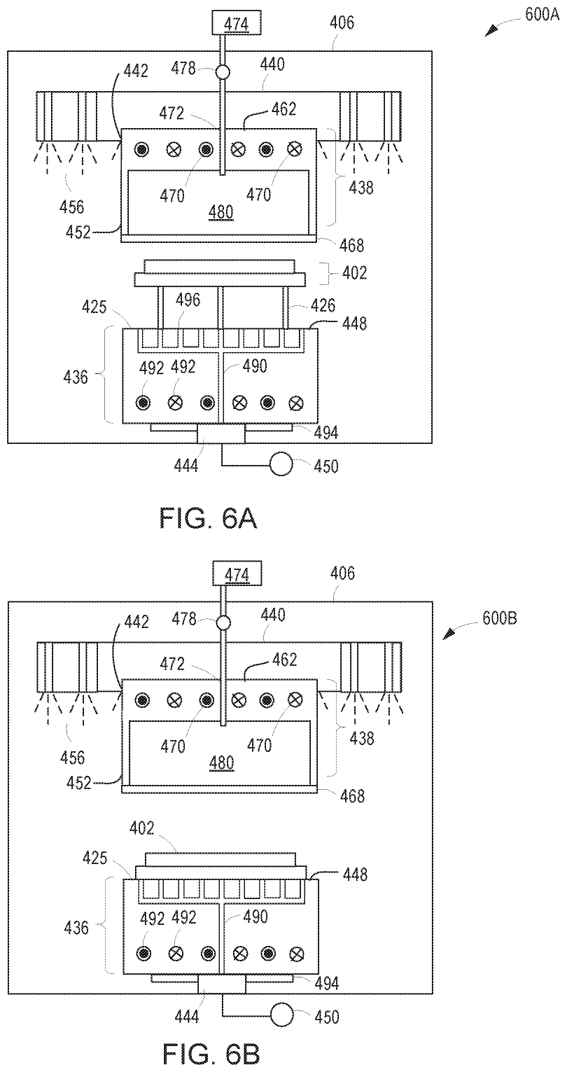

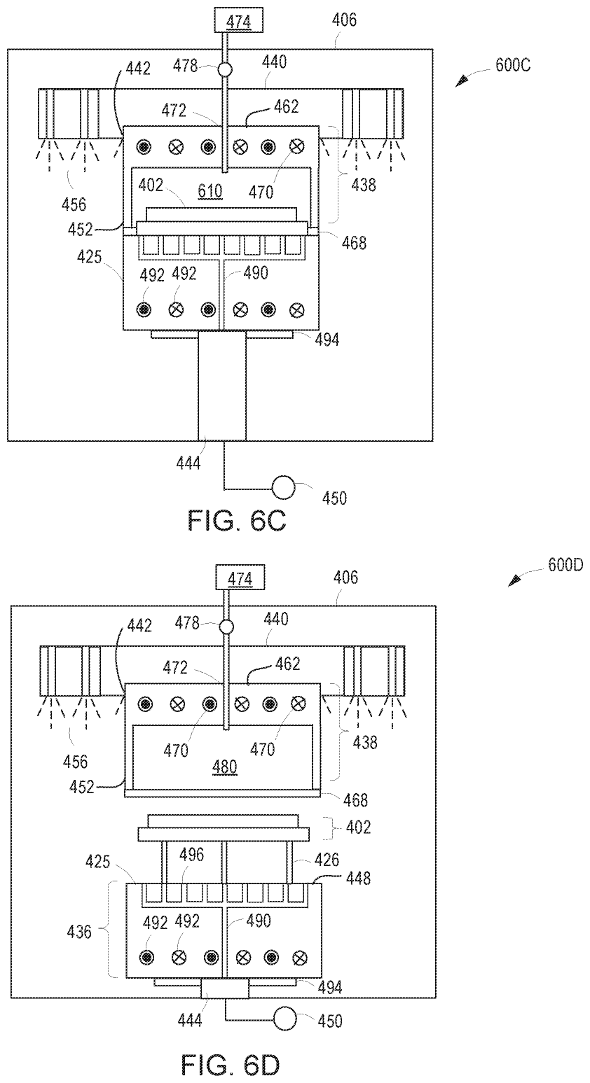

The second station 406 includes a first cooling module 436, a second cooling module 438 disposed opposite the first cooling module 436, and a gas distribution assembly 440. At least one of the first cooling module 436 an the second cooling module 438 are moveable between a transfer position, where the first cooling module 436 is spaced from the second cooling module 438, and a process position, where the first cooling module 436 interfaces with the second cooling module 438 to define an enclosed volume therebetween (e.g., enclosed volume 610 of FIG. 6C). The enclosed volume is sealable and pressurizable. In some embodiments, at least one of the first cooling module 436 and the second cooling module 438 includes a seal 468 disposed at an interface between the first cooling module 436 and the second cooling module 438 to seal the enclosed volume. In some embodiments, the seal 468 is configured to withstand greater than about 10,000N (newtons) of force. In some embodiments, the seal 468 has a maximum compression of about 30 percent.

In some embodiments, the first cooling module 436 may be affixed to an actuator 444 that is configured to move the first cooling module 436 in an upward and downward direction 446. In some embodiments, the second cooling module 438 may be held in a fixed position while the first cooling module 436 is moved upward by the actuator 444 when the substrate 402 is on the first cooling module 436 to define the enclosed volume therebetween. In some embodiments, the second cooling module 438 may be movable while the first cooling module 436 may remain in a fixed position to define the enclosed volume therebetween. In some embodiments, the first cooling module 436 may move upward and the second cooling module 438 may move downward to define the enclosed volume therebetween.

The first cooling module 436 includes a substrate support 425 having a substrate support surface 448. In some embodiments, the second cooling module 438 may also include a lift pin assembly 494 with a plurality of lift pins 426 that are configured to raise and lower 454 the substrate 402 on and off of the substrate support surface 448. In such embodiments, the substrate support 425 includes openings to allow the plurality of lift pins 426 to pass through the substrate support 425. In some embodiments, a vacuum chuck is operatively coupled to the substrate support surface 448. The vacuum chuck includes vacuum channels 490 fluidly coupled to a pump 450. In some embodiments, the vacuum channels 490 extend from a single inlet on a bottom surface of the substrate support 425 to a plurality of outlets 496 on the substrate support surface 448. In some embodiments, the vacuum channels 490 include a vertical portion and a horizontal portion that extends radially outward from the vertical portion.

The second cooling module 438 includes a body 462 and sidewalls 452 extending from the body 462 towards the first cooling module 436. In some embodiments, the body 462 includes a gas channel 472 extending through the body 462 to provide a gas supply to a processing region 480 disposed between the sidewalls 452 and the body 462. The gas channel 472 is fluidly coupled to a gas source 474 to supply a high pressure gas to the substrate 402 via the processing region 480. A valve 478 may be disposed between the gas source 474 and the gas channel 472 to control at least one of a flow rate and a pressure of the gas supplied to the processing region 480. In some embodiments, the valve 478 is a gate valve, or the like.

The gas distribution assembly 440 is configured to provide hot gas into the second station 406 to facilitate in maintaining the at least the glass transition temperature of the epoxy material in the substrate 402 until the substrate 402 is constrained by the first cooling module 436 and the second cooling module 438. In some embodiments, the gas distribution assembly 428 provides a gas at a temperature of approximately 200 degrees Celsius to approximately 300 degrees Celsius. In some embodiments, the gas distribution assembly 440 provides a gas at a temperature of approximately 240 degrees Celsius. In some embodiments, the gas distribution assembly 440 provides a gas at a pressure of approximately 1 bar to approximately 2.5 bar. In some embodiments, the gas distribution assembly 440 provides a gas at a pressure of approximately 1 bar to approximately 2 bar. In some embodiments, the gas may be nitrogen, nitrogen/air, and/or other inert gases.

In some embodiments, the gas distribution assembly 440 is an annular gas distribution assembly 702 as illustrated in FIG. 7 which shows a bottom view of the annular gas distribution assembly 702. The gas distribution assembly 440 or the annular gas distribution assembly 702 includes at least one gas opening 704 and is configured to project heated gas around the substrate 402 to maintain the temperature of the substrate 402. In FIG. 7, the annular gas distribution assembly 702 provides a ring of heated gas in proximity of an outer periphery 706 of the first cooling module 436. In some embodiments, as illustrated in FIG. 4, the gas distribution assembly 440 may encompass an upper portion 442 of the first cooling module 436.

In some embodiments, the first cooling module 436 includes cooling channels 492 that are configured to rapidly cool a bottom surface of the substrate 402 via a coolant that flows therethrough. The cooling channels 492 are disposed beneath the substrate support surface 448. In some embodiments, the body is formed of an aluminum material. In some embodiments, the body 462 includes cooling channels 470 that are vacuum brazed. The vacuum brazing allows the cooling channels 470 to be formed without using copper liners, advantageously increasing thermal conductivity.

In some embodiments, the body 462 includes cooling channels 470 that are configured to rapidly cool a top surface of the substrate 402 via a coolant that flows therethrough. In some embodiments, the body is formed of an aluminum material. In some embodiments, the body 462 includes cooling channels 470 that are vacuum brazed. The vacuum brazing allows the cooling channels 470 to be formed without using copper liners, advantageously increasing thermal conductivity. In some embodiments, the coolant that flows through cooling channels 470 and cooling channels 492 is water.

The cooling rates of the first cooling module 436 and the second cooling module 438 may be controlled in unison or independently by the system controller 408. The pressure and flow rate of the high pressure gas supplied to the processing region 480 may be controlled by the system controller 408. The independent control of the cooling rates and/or the pressure and flow rate of the high pressure gas advantageously provides for fine tuning of a warpage control process.

During the warpage control process, the lift pins 426 are in the raised position with hot gas 456 being projected from the gas distribution system 440 as the transferable pedestal 422 places the substrate 402 onto the lift pins 426. The transferable pedestal 422 continues to heat the substrate 402 with the heater 424 as the substrate 402 is moved from the first station 404 to the second station 406. The transferable pedestal 422 places the substrate 402 onto the lift pins 426 and retreats back to the first station 404 as illustrated in view 600A of FIG. 6A. The lift pins 426 are then lowered until the substrate 402 rests on the substrate support surface 448 of the second cooling module 438 while the hot gas 456 is continued to be projected around the substrate 402 to maintain the temperature of the substrate 402 as illustrate in view 600B of FIG. 6B.

The substrate 402 is then raised into position between the first cooling module 436 and the second cooling module 438 by the actuator 444. In a process position, the sidewalls 452 are configured to interface and form a seal with the substrate support 425 such that an enclosed volume 610 is defined between the sidewalls 452, the body 462, and the substrate support 425. As such, the substrate support surface 448 is disposed between the first cooling module 436 and the second cooling module 438. In the process position, the hot gas 456 stops and a cooling process begins as illustrated in view 600C of FIG. 6C. The first cooling module 436 is configured to vacuum chuck the substrate to the substrate support 425 by providing a vacuum pressure to an underside of the substrate 402.

The second cooling module 438 is configured to apply a high pressure gas to the substrate 402 during the cooling process. The high pressure gas provided by the second cooling module 438 advantageously provides a downward clamping force towards the substrate 402 without physically contacting the substrate 402. In some embodiments, a pressure of the high pressure gas at the substrate support surface 448 is about 1.5 bar to about 2.6 bar. As discussed above, the first cooling module 436 and the second cooling module 438 are also configured to provide rapid heat transfer from the substrate 402 in order to cool the substrate 402. After the cooling process, the second cooling module 438 is lowered and the lift pins 426 raise the substrate 402 off of the substrate support surface 448 of the substrate support 425 as illustrated in view 600D of FIG. 6D. The substrate 402 is then removed from the second station 406 for subsequent processing.

FIG. 5 is a top down view of an apparatus 500 for reducing warpage of a substrate in accordance with some embodiments. The substrate is not shown to allow for illustration of further details of a transferable pedestal 516. The apparatus 500 includes a heating station 504, a transfer duct 508, a cooling station 506, and the transferable pedestal 516. The transferable pedestal 516 has several slots 522 that allow for clearance of lift pins 526 of a lower warpage control assembly 530. The slots 522 allow the lift pins 526 to raise and lift the substrate from transferable pedestal 516 and to allow the transferable pedestal 516 to retreat 528 while the substrate remains on top of the lift pins 526. The slots 522 also function as openings for direct temperature readings of a bottom surface of the substrate by heat sensors 532 positioned on a heat sensor assembly 536. In some embodiments, an additional optional heat sensor 534 may be positioned on the heat sensor assembly 536 to read temperatures of the bottom surface of the substrate not covered by the other heat sensors 532. An optional opening 518 may be incorporated into the transferable pedestal 516 to allow direct temperature readings by the optional heat sensor 534.

In some embodiments, the transferable pedestal 516 has a projection 514 that interacts with a rod 512 driven by an actuator 510. In some embodiments, the projection 514 may include an insulated portion 538 that prevents the transferable pedestal 516 from heating the rod 512 and actuator 510. The actuator 510 is in communication with the system controller (e.g., 408 of FIG. 4) to control the movement 520 of the transferable pedestal 516 between the heating station 504 and the cooling station 506. The transfer duct 508 provides an insulative buffer between the heating station 504 and the cooling station 506.

While the foregoing is directed to embodiments of the present disclosure, other and further embodiments of the disclosure may be devised without departing from the basic scope thereof.

1. A method for reducing warpage of a substrate, comprising:
heating the substrate with an epoxy layer to at least a glass transition temperature of the epoxy layer while allowing the substrate to expand;
subsequently constraining the substrate with a clamping force exerted towards the substrate from a top direction by applying a high pressure gas to the substrate and from a bottom direction by applying a vacuum pressure to the substrate; and
rapidly cooling the substrate while the substrate is constrained.

2. The method of claim 1, further comprising:
maintaining the at least the glass transition temperature of the substrate until the substrate is constrained.

3. The method of claim 1, further comprising:
constraining the substrate with a clamping force of approximately 5,000N to approximately 10,000N.

4. The method of claim 1, wherein applying vacuum pressure comprises drawing vacuum through one or more vacuum channels distributed across a substrate support disposed below the substrate.

5. The method of claim 1, further comprising:
using at least one liquid convection heat sink to rapidly quench cool the substrate at a rate of approximately 1300 W/m^{2°}C to approximately 3100 W/m^{2°}C to retain an elongated and low stress state of the epoxy layer.

6. The method of claim 1, wherein a pressure of the high pressure gas at a substrate support surface is about 1.5 bar to about 2.6 bar.

7. The method of claim 1, further comprising: transferring the substrate from a first station to a second station prior to constraining the substrate with a clamping force.

8. The method of claim 1, further comprising:
concurrently constraining the substrate, cooling the substrate, applying the vacuum pressure to the substrate, and applying the high pressure gas for approximately 60 seconds to approximately 600 seconds.

9. A non-transitory, computer readable medium having instructions stored thereon that, when executed, cause a method of reducing warpage of a substrate to be performed, the method comprising:
heating the substrate with an epoxy layer to at least a glass transition temperature of the epoxy layer while allowing the substrate to expand;
subsequently constraining the substrate with a clamping force exerted towards the substrate from a top direction by applying a high pressure gas to the substrate and from a bottom direction by applying a vacuum pressure to the substrate; and
rapidly cooling the substrate while the substrate is constrained.

10. The non-transitory, computer readable medium of claim 9, further comprising:
heating the substrate to a glass transition temperature of approximately 100 degrees Celsius to approximately 200 degrees Celsius.

11. The non-transitory, computer readable medium of claim 9, wherein constraining the substrate comprises providing a clamping force of approximately 5000N to approximately 10000N exerted towards the substrate.

12. The non-transitory, computer readable medium of claim 9, further comprising:
concurrently constraining the substrate, cooling the substrate, applying the vacuum pressure to the substrate, and applying the high pressure gas to the substrate for approximately 60 seconds to approximately 600 seconds.

13. An apparatus for reducing warpage of a substrate with an epoxy layer, comprising:
a first station comprising a transferable pedestal that holds the substrate, and a heated gas supply disposed opposite the substrate to provide a heated gas to a surface of the substrate, wherein the first station is configured to heat the substrate to at least a glass transition temperature of the epoxy layer;
a second station comprising a first cooling module having a substrate support that includes a substrate support surface, a vacuum chuck operatively coupled to the substrate support surface, and cooling channels disposed beneath the substrate support surface, and a second cooling module disposed opposite the first cooling module and having a gas supply and cooling channels, wherein the second station is sealable and pressurizable to create an enclosed volume having the substrate support surface disposed between the first cooling module and the second cooling module and to provide gas from the gas supply at a high pressure to the enclosed volume; and
wherein the first station and the second station are configured to transfer the substrate between the first station and the second station with the transferable pedestal while maintaining the at least the glass transition temperature of the substrate.

14. The apparatus of claim 13, wherein the second station has a lift pin assembly for raising and lowering the substrate on and off of a substrate support surface of the substrate support.

15. The apparatus of claim 13, the first station further comprising:
a gas distribution assembly located at a top of the first station; and
a heater positioned under the transferable pedestal,
wherein the first station is configured to heat the substrate with a heated gas supplied by the gas distribution assembly from above the substrate and to heat the substrate with the heater from below the substrate.

16. The apparatus of claim 13, the first station further comprising:
one or more infrared heat sensors located at a bottom of the first station and configured to detect a temperature of a bottom surface of the substrate, wherein the transferable pedestal has openings that permit direct readings from the bottom surface of the substrate by the one or more infrared heat sensors.

17. The apparatus of claim 13, the second station further comprising:
an annular gas distribution assembly positioned at a top of the second station and outward of the second cooling module, wherein the annular gas distribution assembly is configured to surround the substrate with heated gas to maintain the at least the glass transition temperature of the substrate.

18. The apparatus of claim 13, further comprising a seal disposed at an interface between the first cooling module and the second cooling module to seal the enclosed volume.

19. The apparatus of claim 13, wherein the first cooling module is moveable between a transfer position, where the first cooling module is spaced from the second cooling module, and a process position, where the second cooling module interfaces with and forms a seal with the first cooling module to create the enclosed volume.

20. The apparatus of claim 19, wherein the second cooling module includes a body and sidewalls extending from the body towards the first cooling module, wherein the sidewalls are configured to interface and form a seal with the substrate support such that the enclosed volume is defined between the sidewalls, the body, and the substrate support.
